(19) United States
(12) Patent Application Publication
(10) Pub. No.: US 2025/0357174 A1
(43) Pub. Date: Nov. 20, 2025

(54) SUBSTRATE SUPPORT AND METHOD OF REGENERATING SUBSTRATE SUPPORT

(71) Applicant: Tokyo Electron Limited, Tokyo (JP)

(72) Inventors: Lifu LI, Miyagi (JP); Yuichi TAKAHASHI, Miyagi (JP)

(21) Appl. No.: 19/286,885

(22) Filed: Jul. 31, 2025

Related U.S. Application Data
(63) Continuation of application No. PCT/JP2024/003958, filed on Feb. 6, 2024.

(30) Foreign Application Priority Data
Feb. 13, 2023 (JP) 2023-020288

(51) Int. Cl. H01L 21/683; H01J 37/32

(52) U.S. Cl. CPC H01L 21/6833; H01J 37/32724; H01J 37/32091

(57) ABSTRACT

A substrate support includes a main body portion having a substrate supporting surface and a back surface opposite to the substrate supporting surface, the main body portion having a through-hole extending from the back surface to the substrate supporting surface, an upper porous plug and a lower porous plug disposed in the through-hole, at least one of the upper porous plug or the lower porous plug being detachable from the main body, and a plurality of fluid particles filling a space between the upper porous plug and the lower porous plug in the through-hole. Each of the plurality of fluid particles is formed of an Si-containing material or a resinous material and an Si-containing coating on the resinous material.

### CROSS-REFERENCE TO RELATED APPLICATIONS

This application is a continuation application of International Application No. PCT/JP2024/003958 filed on Feb. 6, 2024, and designated the U.S., which is based upon and claims priority to Japanese Patent Application No. 2023-020288 filed on Feb. 13, 2023, the entire contents of which are incorporated herein by reference.

### BACKGROUND

### 1. Technical Field

The present disclosure relates to a substrate support and a method of regenerating the substrate support.

### 2. Description of Related Art

PCT Japanese Translation Patent Publication No. 2022-535508 (hereinafter “Patent Document 1”) discloses a substrate support pedestal including an electrostatic chuck, a cooling base, a gas flow path formed between an upper surface of the electrostatic chuck and a bottom surface of the cooling base and including a cavity, and a porous plug disposed in the cavity.

### SUMMARY

According to an aspect of the present disclosure, a substrate support includes a main body portion having a substrate supporting surface and a back surface opposite to the substrate supporting surface, the main body portion having a through-hole extending from the back surface to the substrate supporting surface; an upper porous plug and a lower porous plug disposed in the through-hole, at least one of the upper porous plug or the lower porous plug being detachable from the main body; and a plurality of fluid particles filling a space between the upper porous plug and the lower porous plug in the through-hole. Each of the plurality of fluid particles is formed of (i) an Si-containing material or (ii) a resinous material and an Si-containing coating on the resinous material.

### BRIEF DESCRIPTION OF THE DRAWINGS

FIG. 1 is a diagram illustrating a configuration example of a capacitively coupled plasma processing apparatus;

FIG. 2 is a cross-sectional view of a support base main body of a substrate support portion according to a first embodiment;

FIG. 3 is a cross-sectional view of a support base main body of a substrate support portion according to a second embodiment;

FIG. 4 is a cross-sectional view of the support base main body of the substrate support portion according to the second embodiment during heat input;

FIG. 5A is a diagram illustrating an example of fluid particles;

FIG. 5B is a diagram illustrating an example of fluid particles;

FIG. 5C is a diagram illustrating an example of fluid particles;

FIG. 6A is a cross-sectional view of an electrostatic chuck in each step of a process of regenerating a substrate support portion;

FIG. 6B is a cross-sectional view of an electrostatic chuck in each step of a process of regenerating a substrate support portion;

FIG. 6C is a cross-sectional view of an electrostatic chuck in each step of a process of regenerating a substrate support portion;

FIG. 7A is a cross-sectional view of a support base main body of a substrate support portion according to another embodiment;

FIG. 7B is a cross-sectional view of the support base main body of the substrate support portion according to the other embodiment;

FIG. 7C is a cross-sectional view of the support base main body of the substrate support portion according to the other embodiment;

FIG. 8 is an example of a cross-sectional view illustrating a structure between a lower electrode and a plasma processing chamber in the plasma processing apparatus; and

FIG. 9 is an example of a cross-sectional view illustrating a structure between an upper electrode and the plasma processing chamber in the plasma processing apparatus.

### DETAILED DESCRIPTION

According to one aspect, a substrate support that suppresses abnormal discharge and a method of regenerating the substrate support can be provided.

Hereinafter, various exemplary embodiments will be described in detail with reference to the drawings. In the drawings, the same or corresponding parts are denoted by the same reference numerals.

### <Plasma Processing System>

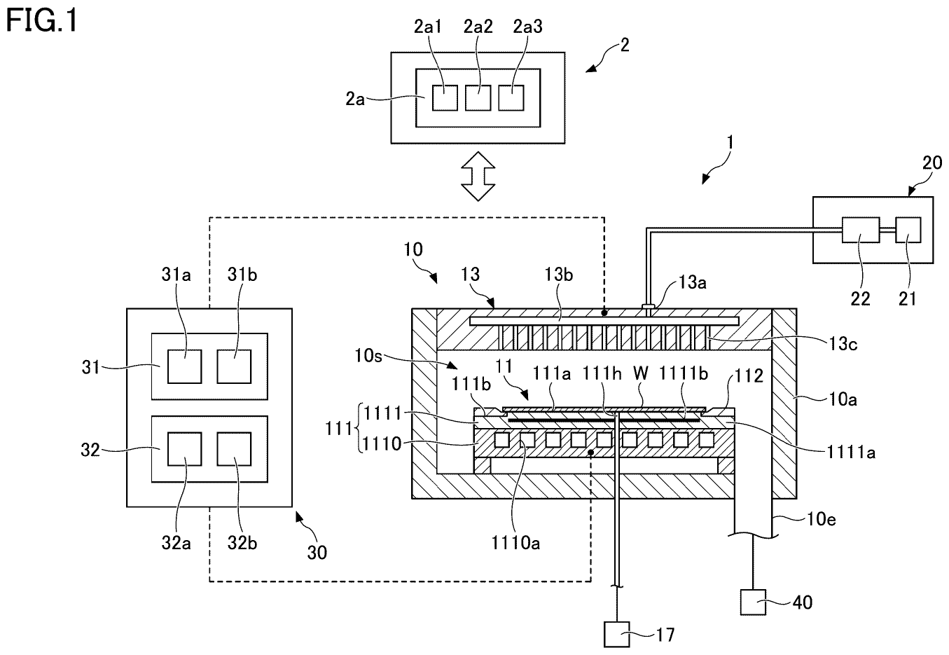

Hereinafter, a configuration example of the plasma processing system will be described. FIG. 1 is a diagram illustrating a configuration example of a capacitively coupled plasma processing apparatus 1.

The plasma processing system includes a capacitively coupled plasma processing apparatus 1 and a controller 2. The capacitively coupled plasma processing apparatus 1 includes a plasma processing chamber 10, a gas supply 20, a power source 30, and an exhaust system 40. The plasma processing apparatus 1 includes a substrate support portion (substrate support) 11 and a gas introducer. The gas introducer is configured to introduce at least one processing gas into the plasma processing chamber 10. The gas introducer includes a shower head 13. The substrate support portion 11 is disposed in the plasma processing chamber 10. The shower head 13 is disposed above the substrate support portion 11. In one embodiment, the shower head 13 constitutes at least a part of the ceiling of the plasma processing chamber 10. The plasma processing chamber 10 has a plasma processing space 10s, which is defined by the shower head 13, a sidewall 10a of the plasma processing chamber 10, and the substrate support portion 11. The plasma processing chamber 10 has at least one gas inlet for supplying at least one processing gas to the plasma processing space 10s and at least one gas outlet for discharging a gas from the plasma processing space 10s. The plasma processing chamber 10 is grounded. The shower head 13 and the substrate support portion 11 are electrically insulated from a housing of the plasma processing chamber 10.

The substrate support portion 11 includes a support base main body 111 and a ring assembly 112. The support base main body 111 has a central region 111a for supporting a substrate W and an annular region 111b for supporting the ring assembly 112. A wafer is an example of a substrate W. The annular region 111b of the support base main body 111 surrounds the central region 111a of the support base main body 111 in plan view. A substrate W is disposed on the central region 111a of the support base main body 111, and the ring assembly 112 is disposed on the annular region 111b of the support base main body 111 so as to surround the substrate W disposed on the central region 111a of the support base main body 111. Accordingly, the central region 111a is also referred to as a “substrate supporting surface” for supporting a substrate W, and the annular region 111b is also referred to as a “ring support surface” for supporting the ring assembly 112.

In one embodiment, the support base main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In one embodiment, the ceramic member 1111a also has an annular region 111b. Other members surrounding the electrostatic chuck 1111, such as an annular electrostatic chuck or an annular insulating member, may have an annular region 111b. In this case, the ring assembly 112 may be disposed on the annular electrostatic chuck or the annular insulating member, or may be disposed on both the electrostatic chuck 1111 and the annular insulating member. At least one RF/DC power source coupled to a radio frequency (RF) power source 31 or a direct current (DC) power source 32 or both, which will be described later, may be disposed in the ceramic member 1111a. In this case, at least one RF/DC electrode functions as a lower electrode. In the case where a bias RF signal or a DC signal or both, which will be described later, are supplied to at least one RF/DC electrode, the RF/DC electrode is also referred to as a “bias electrode”. The conductive member of the base 1110 and at least one RF/DC electrode may function as a plurality of lower electrodes. The electrostatic electrode 1111b may function as a lower electrode. Accordingly, the substrate support portion 11 includes at least one lower electrode.

The ring assembly 112 includes one or more annular members. In one embodiment, the one or more annular members include one or more edge rings and at least one cover ring. The edge ring is formed of a conductive or insulating material, and the cover ring is formed of an insulating material.

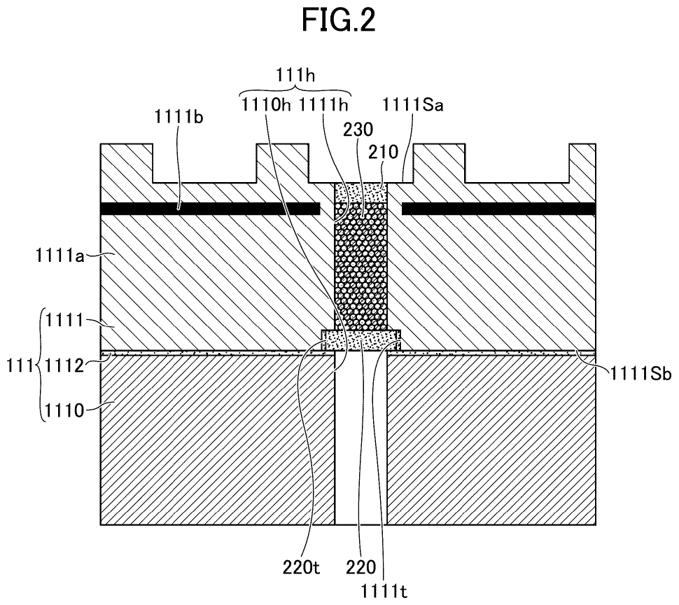

The substrate support portion 11 may include a temperature control module configured to control at least one of the electrostatic chuck 1111, the ring assembly 112, or a substrate W to a target temperature. The temperature control module may include a heater, a heat transfer medium, a flow path 1110a, or a combination thereof. A heat transfer fluid, such as a brine or a gas flows through the flow path 1110a. In one embodiment, the flow path 1110a is formed in the base 1110 and the one or more heaters are disposed in the ceramic member 1111a of the electrostatic chuck 1111. The substrate support portion 11 may include a heat transfer gas supply 17 configured to supply a heat transfer gas to a gap between the back surface of a substrate W and the central region 111a. The heat transfer gas supply 17 is configured to supply a heat transfer gas (for example, helium (He) gas) to a through-hole 111h (through-holes 1110h and 1111h described later with reference to FIG. 2) formed in the support base main body 111.

The shower head 13 is configured to introduce at least one processing gas from the gas supply 20 into the plasma processing space 10s. The shower head 13 includes at least one gas inlet 13a, at least one gas diffusion chamber 13b, and a plurality of gas introducing ports 13c. A processing gas supplied to the gas inlet 13a passes through the gas diffusion chamber 13b and is introduced into the plasma processing space 10s through the plurality of gas introducing ports 13c. The shower head 13 includes at least one upper electrode. The gas introducer may include, in addition to the shower head 13, one or more side gas injectors (SGI) attached to one or more openings formed in the sidewall 10a.

The gas supply 20 may include at least one gas source 21 and at least one flow rate controller 22. In one embodiment, the gas supply 20 is configured to supply at least one processing gas from a corresponding gas source 21 to the shower head 13 via a corresponding flow rate controller 22. Each flow rate controller 22 may include, for example, a mass flow controller or a pressure-controlled flow rate controller. The gas supply 20 may further include one or more flow rate modulation devices that modulate or pulse a flow rate of at least one processing gas.

The power source 30 includes the RF power source 31 coupled to the plasma processing chamber 10 through at least one impedance matching circuit. The RF power source 31 is configured to supply at least one RF signal (RF power) to at least one lower electrode and at least one upper electrode or both. Accordingly, plasma is formed from at least one processing gas supplied to the plasma processing space 10s. Accordingly, the RF power source 31 may function as at least a part of a plasma generator configured to generate plasma from one or more processing gases in the plasma processing chamber 10. A bias potential is generated in a substrate W by supplying a bias RF signal to at least one lower electrode, and an ion component in the generated plasma can be thereby attracted to the substrate W.

In one embodiment, the RF power source 31 includes a first RF generator 31a and a second RF generator 31b. The first RF generator 31a is coupled to at least one lower or at least one upper electrode or both via at least one impedance matching circuit and configured to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode or at least one upper electrode or both.

The second RF generator 31b is coupled to at least one lower electrode via at least one impedance matching circuit and configured to generate a bias RF signal (bias RF power). The frequency of the bias RF signal may be the same as or different from the frequency of the source RF signal. In one embodiment, the bias RF signal has a frequency that is lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal or the bias RF signal may be pulsed.

The power source 30 may also include the DC power source 32 coupled to the plasma processing chamber 10. The DC power source 32 includes a first DC generator 32a and a second DC generator 32b. In one embodiment, the first DC generator 32a is connected to at least one lower electrode and configured to generate a first DC signal. The generated first bias DC signal is supplied to at least one lower electrode. In one embodiment, the second DC generator 32b is connected to at least one upper electrode and configured to generate a second DC signal. The generated second DC signal is supplied to at least one upper electrode.

In various embodiments, at least one of the first DC signal or the second DC signal may be pulsed. In this case, a sequence of voltage pulses is applied to at least one lower electrode or at least one upper electrode or both. The voltage pulse may have a pulse waveform of a rectangular shape, a trapezoidal shape, a triangular shape, or a combination thereof. In one embodiment, a waveform generator for generating a sequence of voltage pulses from a DC signal is connected between the first DC generator 32a and at least one lower electrode. Therefore, the first DC generator 32a and the waveform generator constitute a voltage pulse generator. In the case where the second DC generator 32b and the waveform generator constitute a voltage pulse generator, the voltage pulse generator is connected to at least one upper electrode. The voltage pulse may have a positive polarity or a negative polarity. The sequence of voltage pulses may include one or more positive voltage pulses and one or more negative voltage pulses in one cycle. The first and second DC generators 32a and 32b may be provided in addition to the RF power source 31, or the first DC generator 32a may be provided instead of the second RF generator 31b.

The exhaust system 40 may be connected to, for example, a gas outlet 10e provided at the bottom of the plasma processing chamber 10. The exhaust system 40 may include a pressure regulating valve and a vacuum pump. The pressure in the plasma processing space 10s is regulated by the pressure regulating valve. The vacuum pump may include a turbomolecular pump, a dry pump, or a combination of a turbomolecular pump and a dry pump.

The controller 2 processes computer-executable instructions that cause the plasma processing apparatus 1 to perform various processes described in the present disclosure. The controller 2 may be configured to control the respective components of the plasma processing apparatus 1 to perform various processes described in the present disclosure. In one embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2al may be configured to read a program from the storage 2a2 and execute the read program to perform various control operations. This program may be stored in the storage 2a2 in advance, or may be acquired via media when necessary. The acquired program is stored in the storage 2a2, and is read from the storage 2a2 and executed by the processor 2al. The media may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination of these components. The communication interface 2a3 may communicate with the plasma processing apparatus 1 via a communication line such as a local area network (LAN).

Herein, the substrate support portion 11 is formed with a through-hole 111h for supplying a heat transfer gas (e.g., helium gas) to the back surface side of a substrate W. When plasma processing is performed on a substrate W, a heat transfer gas fills the gap between the back surface of the substrate W and the substrate supporting surface, and the heat transfer gas also fills the through-hole 111h. When plasma processing is performed on a substrate W in the substrate support portion 11, a potential difference in the up-down direction (of the drawing) is generated between the substrate W supported on the substrate supporting surface and the base 1110 functioning as a lower electrode. Due to this potential difference, there is a possibility that abnormal discharge occurs in the through-hole 111h. Due to an occurrence of abnormal discharge, the electrostatic chuck 1111 may be consumed or a discharge mark may be formed on the back surface side of the substrate W.

An example of a structure for suppressing abnormal discharge will be described with reference to FIG. 2. FIG. 2 is a cross-sectional view of the support base main body 111 of the substrate support portion 11 according to the first embodiment.

The support base main body 111 includes the base 1110, the electrostatic chuck 1111, and an adhesive layer 1112. The ceramic member (also referred to as a “main body” in the first embodiment) 1111a of the electrostatic chuck 1111 is fixed on the base (conductive base) 1110 including a conductive member via the adhesive layer 1112.

The ceramic member 1111a of the electrostatic chuck 1111 has a substrate supporting surface (upper surface) 1111S1 and a back surface (lower surface) 1111S2 opposite to the substrate supporting surface 1111S1. The back surface 1111S2 is a surface bonded to the base 1110 via the adhesive layer 1112. A through-hole 1111h extending from the back surface 1111S2 to the substrate supporting surface 1111S1 is formed in the ceramic member 1111a of the electrostatic chuck 1111.

The base 1110 has an upper surface and a lower surface. The upper surface of the base 1110 is a surface bonded to the ceramic member 1111a via the adhesive layer 1112. The lower surface of the base 1110 is a surface opposite to the upper surface of the base 1110. The through-hole 1110h extending from the lower surface to the upper surface is formed in the base 1110.

The through-hole 111h includes the through-hole 1110h and the through-hole 1111h. The through-hole 1110h and the through-hole 1111h are formed, for example, coaxially so that a heat transfer gas can flow through each other.

An upper porous plug 210 and a lower porous plug 220 are provided in the through-hole 1111h formed in the ceramic member 1111a.

The upper porous plug 210 and the lower porous plug 220 have a porous structure in which a heat transfer gas can flow in an axial direction (the up-down direction in the example of FIG. 2) of the through-hole 1111h. The upper porous plug 210 and the lower porous plug 220 can shorten a moving distance (mean free path) of electrons in a voltage application direction (the vertical direction, the up-down direction) in the space where the upper porous plug 210 and the lower porous plug 220 are provided. This makes it possible to suppress abnormal discharge of a heat transfer gas in the upper porous plug 210 and the lower porous plug 220.

At least one of the upper porous plug 210 or the lower porous plug 220 is detachably provided in the ceramic member 1111a. In the example illustrated in FIG. 2, the upper porous plug 210 is fixed to the ceramic member 1111a, and the lower porous plug 220 is detachably provided in the ceramic member 1111a. For example, a female screw portion 1111t is formed in the ceramic member 1111a. The lower porous plug 220 is formed in a substantially cylindrical shape, and a male screw portion 220t to be screwed with the female screw portion 1111t is formed on the circumferential surface.

Thus, the lower porous plug 220 is detachably provided in the ceramic member 1111a.

In the example illustrated in FIG. 2, the case where the lower porous plug 220 is detachably provided has been described as an example, but the present invention is not limited thereto, and the upper porous plug 210 may be detachably provided in the ceramic member 1111a. Both of the upper porous plug 210 and the lower porous plug 220 may be detachably provided in the ceramic member 1111a.

In the through-hole 1111h, a plurality of fluid particles 230 fill a space between the upper porous plug 210 and the lower porous plug 220. Herein, the plurality of fluid particles 230 are particles that can flow along a shape of the space to be filled. A plurality of fluid particles 230 fill the through-hole 1111h between the upper porous plug 210 and the lower porous plug 220. A heat transfer gas can flow through gaps between the plurality of fluid particles 230. In the through-hole 1111h filled with the plurality of fluid particles 230, a moving distance (mean free path) of electrons in a voltage application direction (the vertical direction, the up-down direction) can be shortened. This can suppress abnormal discharge of a heat transfer gas in the through-hole 1111h filled with the plurality of fluid particles 230.

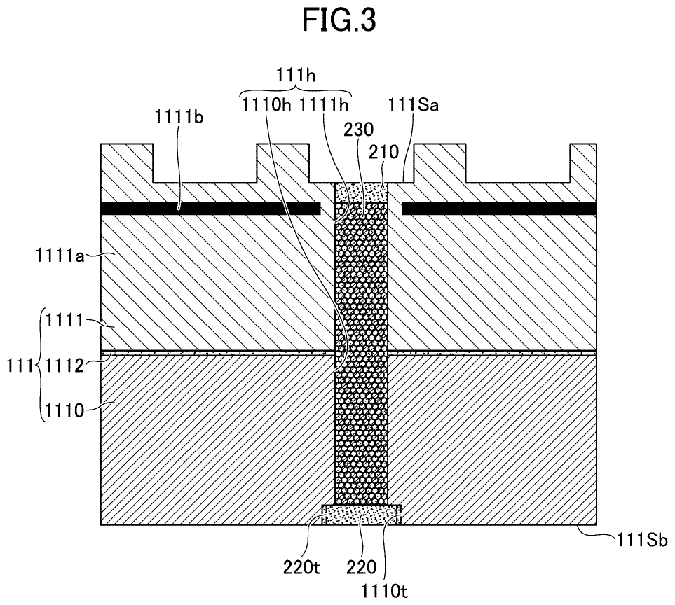

Next, another example of a structure for suppressing abnormal discharge will be described with reference to FIG. 3. FIG. 3 is a cross-sectional view of the support base main body 111 of the substrate support portion 11 according to the second embodiment.

The support base main body (also referred to as a “main body” in the second embodiment) 111 includes the base 1110, the electrostatic chuck 1111, and the adhesive layer 1112. The ceramic member 1111a of the electrostatic chuck 1111 is fixed on the base (conductive base) 1110 including a conductive member via the adhesive layer 1112.

The support base main body 111 has a substrate supporting surface (upper surface) 111S1 and a back surface (lower surface) 111S2 which is a surface opposite to the substrate supporting surface 111S1.

The ceramic member 1111a of the electrostatic chuck 1111 has an upper surface (the substrate supporting surface 111S1 of the support base main body 111) and a lower surface. The lower surface of the electrostatic chuck 1111 is a surface that is bonded to the base 1110 via the adhesive layer 1112. The through-hole (upper through-hole) 1111h extending from the lower surface to the upper surface (the substrate supporting surface 111S1 of the support base main body 111) is formed in the ceramic member 1111a of the electrostatic chuck 1111.

The base 1110 has an upper surface and a lower surface (a back surface 11152 the support base main body 111). The upper surface of the base 1110 is a surface bonded to the ceramic member 1111a via the adhesive layer 1112. The through-hole (lower through-hole) 1110h extending from the lower surface (the back surface 111S2 of the support base main body 111) to the upper surface is formed in the base 1110.

The through-hole 111h includes the through-hole 1110h and the through-hole 1111h. The through-hole 1110h and the through-hole 1111h are formed, for example, coaxially so that a heat transfer gas can flow through each other.

The upper porous plug 210 and the lower porous plug 220 are provided in the through-hole 111h formed in the support base main body 111. Specifically, the upper porous plug 210 is disposed in the through-hole (upper through-hole) 1111h. The lower porous plug 220 is disposed in the through-hole (lower through-hole) 1110h.

The upper porous plug 210 and the lower porous plug 220 have a porous structure in which a heat transfer gas can flow in an axial direction (the up-down direction in the example of FIG. 3) of the through-hole 111h. The upper porous plug 210 and the lower porous plug 220 can shorten a moving distance (mean free path) of electrons in a voltage application direction (the vertical direction, the up-down direction) in the space where the upper porous plug 210 and the lower porous plug 220 are provided. This makes it possible to suppress abnormal discharge of a heat transfer gas in the upper porous plug 210 and the lower porous plug 220.

At least one of the upper porous plug 210 or the lower porous plug 220 is detachably provided in the support base main body 111. In the example illustrated in FIG. 3, the upper porous plug 210 is fixed to the ceramic member 1111a, and the lower porous plug 220 is detachably provided in the base 1110. For example, the female screw portion 1110t is formed in the base 1110. The lower porous plug 220 is formed in a substantially cylindrical shape, and the male screw portion 220t to be screwed with the female screw portion 1110t is formed on the circumferential surface. Thus, the lower porous plug 220 is detachably provided in the base 1110.

In the example illustrated in FIG. 3, the case where the lower porous plug 220 is detachably provided has been described as an example, but the present invention is not limited thereto, and the upper porous plug 210 may be detachably provided in the ceramic member 1111a. Both of the upper porous plug 210 and the lower porous plug 220 may be detachably provided in the support base main body 111 (the ceramic member 1111a, the base 1110).

In the through-hole 111h, a plurality of fluid particles 230 fill the space between the upper porous plug 210 and the lower porous plug 220. Herein, the plurality of fluid particles 230 are particles that can flow along a shape of the space to be filled. The plurality of fluid particles 230 fill in the through-hole 111h between the upper porous plug 210 and the lower porous plug 220. A heat transfer gas can flow through gaps between the plurality of fluid particles 230. In the through-hole 111h filled with the plurality of fluid particles 230, a moving distance (mean free path) of electrons in a voltage application direction (the vertical direction, the up-down direction) can be shortened. This can suppress abnormal discharge of a heat transfer gas in the through-hole 111h filled with the plurality of fluid particles 230.

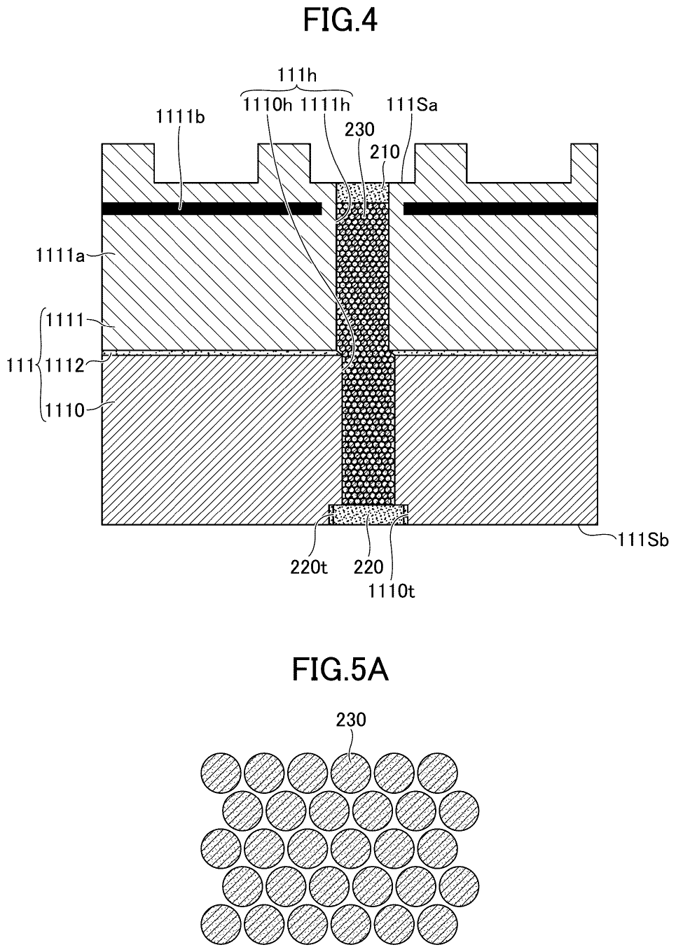

FIG. 4 is a cross-sectional view of the support base main body 111 of the substrate support portion 11 according to the second embodiment during heat input.

The through-hole 111h penetrates the interface between the lower surface of the ceramic member 1111a and the upper surface of the base 1110. During plasma processing, a difference in thermal expansions between the ceramic member 1111a and the base 1110 causes a shift at the interface. As a result, a shift occurs between the position of the axis of the through-hole 1110h and the position of the axis of the through-hole 1111h, and the shape of the through-hole 111h is deformed. In response to this shift, in the support base main body 111 of the substrate support portion 11 according to the second embodiment, the plurality of fluid particles 230 that fill the through-hole 111h can adapt to the deformed shape of the through-hole 111h. Thus, even in the case the shape of the through-hole 111h is deformed due to heat input, a heat transfer gas can flow and abnormal discharge can be suppressed.

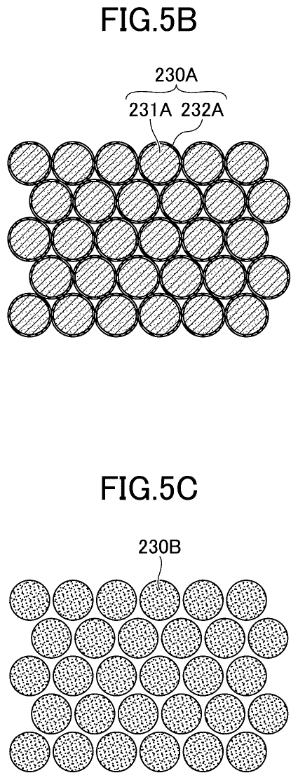

Next, the fluid particles 230 in the support base main body 111 (see FIG. 2) of the substrate support portion 11 according to the first embodiment and the support base main body 111 (see FIGS. 3 and 4) of the substrate support portion 11 according to the second embodiment will be further described. FIGS. 5A through 5C are diagrams schematically illustrating examples of the fluid particles 230, 230A, and 230B.

As illustrated in FIG. 5A, the fluid particles 230 may be particles formed of a solid (bulk, non-porous) material.

For example, the fluid particles 230 may be particles formed of a silicon (Si)-containing material. Specifically, the fluid particles 230 may also be particles formed of silicon as an Si-containing material.

The fluid particles 230 may also be particles formed of SiO₂ as an Si-containing material. In a process of etching Si of a substrate W for example, consumption of the fluid particles 230 can be suppressed by using SiO₂ as the fluid particles 230.

The fluid particles 230 may use any one of Sic, Poly-Si, and the like as an Si-containing material.

The fluid particles 230 may be formed of a ceramic material (e.g., Al₂O₃), a metal (e.g., Al), or a resin (e.g., polytetrafluoroethylene (PTFE)).

As illustrated in FIG. 5B, the fluid particles 230A may be particles formed to have internal particles 231A and a protective film 232A coating the surfaces of the internal particles 231A.

The internal particles 231A may be formed of a resinous material. As the resinous material of the internal particles 231A, for example, polytetrafluoroethylene (PTFE) can be used. As the protective film 232A, an Si-containing coating can be used. SiC may be used as a material of an Si-containing film. Thus, consumption of the fluid particles 230A can be suppressed by coating the internal particles 231A with the protective film 232A having radical resistance and adjusting the dielectric constant or the coefficient of thermal expansion of the fluid particles 230A or both by the material of the internal particles 231A. In one embodiment, each of the plurality of fluid particles 230 is (i) the fluid particle 230 formed of an Si-containing material or (ii) the fluid particle 230A formed of the resinous material 231A and the Si-containing coating 232A on the resinous material 231A. In one embodiment, the plurality of fluid particles 230 includes (i) at least one of the fluid particles 230 formed of an Si-containing material and (ii) at least one of the fluid particles 230A formed of the resinous material 231A and the Si-containing coating 232A on the resinous material 231A.

As illustrated in FIG. 5C, the fluid particles 230C may be particles formed of a porous material (porous material). This makes it possible to improve conductance of a gas flow path while a mean free path is being suppressed. In one embodiment, each of the plurality of fluid particles 230 is (i) the fluid particle 230 formed of an Si-containing material, (ii) the fluid particle 230A formed of the resinous material 231A and the Si-containing coating 232A on the resinous material 231A, or (iii) the fluid particle 230C formed of a porous material. In one embodiment, the plurality of fluid particles 230 includes (i) the fluid particles 230 formed of an Si-containing material, (ii) the fluid particles 230A formed of the resinous material 231A and the Si-containing coating 232A on the resinous material 231A, and (iii) the fluid particles 230C formed of a porous material.

The particle size of the fluid particles 230 (230A, 230B) will be described. Herein, the upper porous plug 210 has a first maximum pore size. The lower porous plug 220 has a second maximum pore size. The plurality of fluid particles 230 (230A, 230B) has a particle size greater than the first maximum pore size and the second maximum pore size. With this relationship, the fluid particles 230 filling the space surrounded by the upper porous plug 210 and the lower porous plug 220 can be prevented from flowing out to the outside.

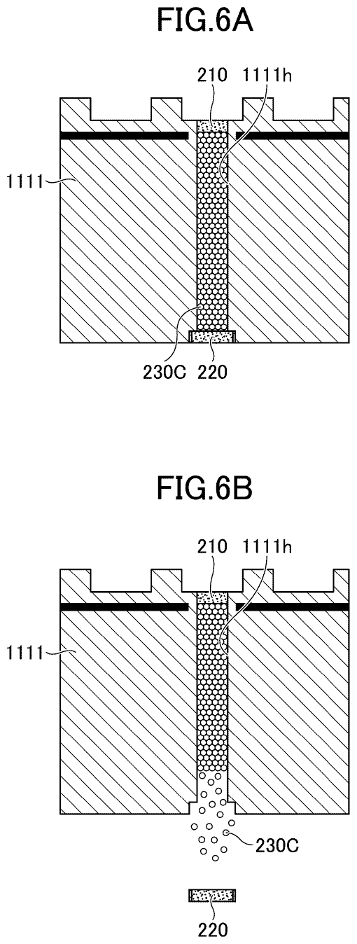

Next, a method of regenerating the substrate support portion 11 will be described with reference to FIGS. 6A through 6C. FIGS. 6A through 6C are a cross-sectional view of the electrostatic chuck 1111 in each step of a process of regenerating the substrate support portion 11. Herein, the case where the upper porous plug 210, the lower porous plug 220, and the fluid particles 230 are arranged in the configuration illustrated in FIG. 2 will be described as an example.

FIG. 6A illustrates the electrostatic chuck 1111 of the used substrate support portion 11. In the used electrostatic chuck 1111, a plurality of used fluid particles 230C fill the through-hole 1111h between the upper porous plug 210 and the lower porous plug 220. The used fluid particles 230C are assumed to be consumed by, for example, plasma.

First, a step of removing the detachable porous plug (at least one of the upper porous plug 210 or the lower porous plug 220) from the ceramic member 1111a is performed. Herein, as illustrated in FIG. 6B, the detachable lower porous plug 220 is removed from the ceramic member 1111a.

Next, a step of removing the plurality of used fluid particles 230C from the through-hole 1111h is performed. Herein, as illustrated in FIG. 6B, the plurality of used fluid particles 230C are removed from the through-hole 1111h. The discharge of the used fluid particles 230C may be accelerated by applying ultrasonic vibration to the ceramic member 1111a.

Next, a step of filling the through-hole 1111h with unused fluid particles 230 is performed. Herein, the through-hole 1111h is filled with a plurality of unused fluid particles 230. When the fluid particles 230 fill the through hole 1111h, ultrasonic vibration may be applied to the ceramic member 1111a. Accordingly, the fluid particles 230 densely fill the through hole 1111h. For example, in the case where the fluid particles 230 are spherical, the fluid particles 230 fill the through-hole 1111h while ultrasonic vibration is being applied, whereby the fluid particles 230 are aligned in the through-hole 1111h, and can have, for example, a hexagonal close-packed structure.

Then, the removed porous plug (at least one of the upper porous plug 210 or the lower porous plug 220) is attached to the ceramic member 1111a. As a result, as illustrated in FIG. 6C, the fluid particles 230 are replaced, and the substrate support portion 11 can be regenerated.

Even in the case where the upper porous plug 210, the lower porous plug 220, and the fluid particles 230 are arranged in the configuration illustrated in FIG. 3, the substrate support portion 11 can be regenerated in the same manner.

Although the case where the removable porous plug is the lower porous plug 220 has been described as an example, the removable porous plug is not limited thereto, and may be the upper porous plug 210. In this case, the fluid particles 230 can be replaced without removing the electrostatic chuck 1111 bonded by the adhesive layer 1112 from the base 1110. When the used fluid particles 230C are removed, a gas may be supplied from below, and the used fluid particles 230C discharged from the through-hole 1111h may be sucked. In this case, the fluid particles 230 can be replaced without removing the base 1110 from the plasma processing chamber 10.

By making the lower porous plug 220 detachable, it is possible to prevent the used fluid particles 230C or the unused fluid particles 230 from adhering to the substrate mounting surface.

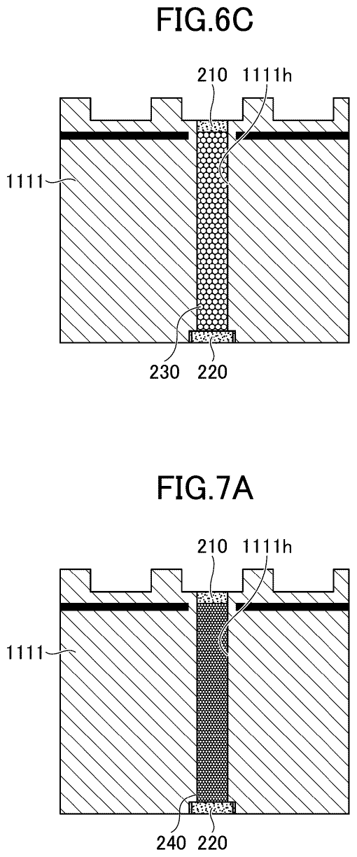

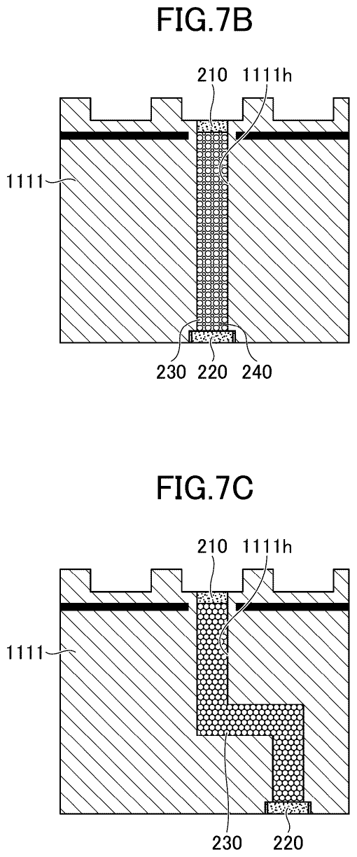

FIGS. 7A through 7C are a cross-sectional view of the support base main body 111 of the substrate support portion 11 according to another embodiment. Herein, the case where the upper porous plug 210, the lower porous plug 220, and the fluid particles 230 are arranged in the configuration illustrated in FIG. 2 will be described as an example. Illustration of the base 1110 is omitted.

In FIG. 7A, an example of a case where fluid particles 240 having a different particle size (the particle size of the fluid particles 240<the particle size of the fluid particles 230) are used is illustrated. As illustrated in FIG. 7A, gaps between the particles can be changed by using the fluid particles 240 having a smaller particle size than the fluid particles 230. In other words, a conductance of a heat transfer gas can be changed.

In FIG. 7B, a plurality of fluid particles (first fluid particles) 230 having a first particle size and a plurality of fluid particles (second fluid particles) 240 having a second particle size smaller than the first particle size fill the through-hole 1111h. In this manner, the through-hole 1111h may be filled with the fluid particles 230 and 240 having different particle sizes.

For example, the first particle size is preferably in the range of 100 μm to 200 μm, and the second particle size is preferably less than 30 μm. Accordingly, the fluid particles 240 having the second particle size fill gaps between the fluid particles 230 having the first particle size, and the mean free path can be further shortened, and an occurrence of abnormal discharge can be suppressed.

The fluid particles 230 and the fluid particles 240 may be formed of the same material. The fluid particles 230 and the fluid particles 240 may be formed of different materials.

In FIG. 7C, the through-hole 1111h is bent in the ceramic member 1111a. The through-hole 1111h having such a shape can also be suitably filled with the fluid particles 230.

As described above, a mean free path can be kept small by filling the space between the upper porous plug 210 and the lower porous plug 220 with the plurality of fluid particles 230 in the through-holes 111h and 1111h through which a heat transfer gas flows.

As illustrated in FIG. 7C, the fluid particles 230 can fill the space in accordance with the shape of the through-holes 111h and 1111h, in other words, the shape of the through-holes 111h and 1111h can be freely selected.

As illustrated in FIG. 5, the flexibility in selecting a material for the fluid particles 230 (230A, 230B) can be improved.

As illustrated in FIG. 6, the substrate support portion 11 can be regenerated by replacing the fluid particles 230.

As in the example illustrated in FIGS. 7A and 7B, a conductance of a heat transfer gas can be controlled by controlling the particle size of the fluid particles 230 and 240.

The structure in which a plurality of fluid particles fill the space between the upper porous plug and the lower porous plug in a gas flow path through which a gas flows may be applied to other configurations.

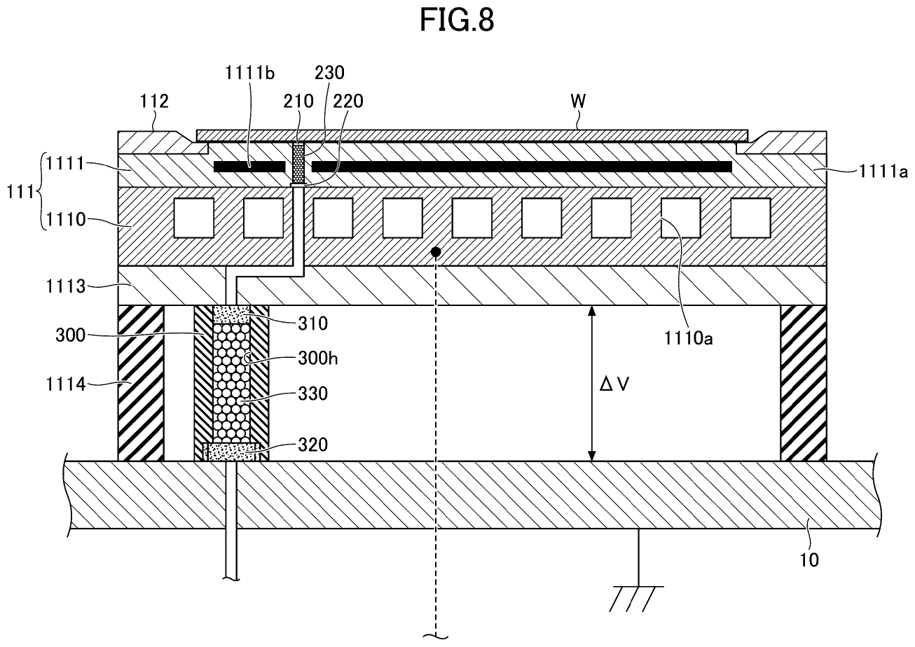

FIG. 8 is an example of a cross-sectional view illustrating a structure between a lower electrode and the plasma processing chamber 10 in the plasma processing apparatus 1.

A conductive member 1113 formed of a conductive material and a conductive member 1114 formed of an insulating material are provided under the base 1110 functioning as a lower electrode.

A flow path forming member 300 for forming a flow path of a heat transfer gas is provided between the plasma processing chamber 10 and the conductive member 1113. The flow path forming member 300 is a substantially cylindrical member formed of an insulating material, and has a through-hole 300h.

Herein, the plasma processing chamber 10 is grounded. At least one of a source RF signal, a bias RF signal, or a DC signal is supplied to the base 1110 functioning as a lower electrode and the conductive member 1113. Accordingly, a potential difference ΔV is generated between the plasma processing chamber 10 and the conductive member 1113. Due to this potential difference, there is a possibility that abnormal discharge occurs in the through-hole 300h.

To address this, the flow path forming member 300 includes an upper porous plug 310 and a lower porous plug 320 disposed in the through-hole 300h, and a plurality of fluid particles 330 that fill the space between the upper porous plug 310 and the lower porous plug 320 in the through-hole 300h. At least one of the upper porous plug 310 or the lower porous plug 320 is detachably provided in the flow path forming member 300. With such a configuration, abnormal discharge can be suppressed.

The upper porous plug 310, the lower porous plug 320, and the fluid particles 330 are similar to the upper porous plug 210, the lower porous plug 220, and the fluid particles 230 (230A, 230B, 240), and thus the redundant description will be omitted.

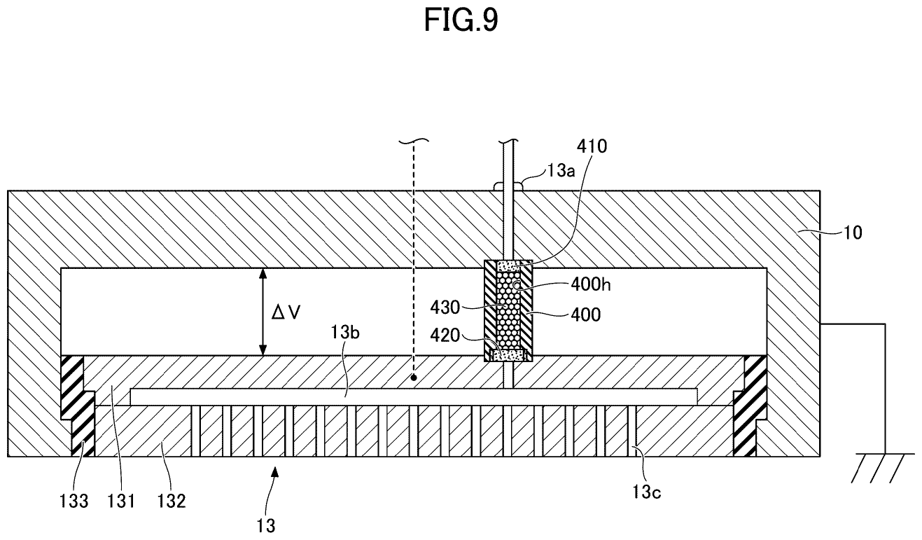

FIG. 9 is an example of a cross-sectional view illustrating a structure between an upper electrode and the plasma processing chamber 10 in the plasma processing apparatus 1.

The shower head 13 serving as an upper electrode includes a cooling plate 131 and an electrode plate 132, which are formed of a conductive member. The cooling plate 131 and the electrode plate 132 are supported by the plasma processing chamber 10 via an insulating member 133.

A flow path forming member 400 that forms a flow path of a process gas is provided between the plasma processing chamber 10 and the cooling plate 131. The flow path forming member 400 is a substantially cylindrical member formed of an insulating material, and has a through-hole 400h.

Herein, the plasma processing chamber 10 is grounded. At least one of a source RF signal, a bias RF signal, or a DC signal is supplied to the cooling plate 131 and the electrode plate 132 functioning as an upper electrode. Accordingly, a potential difference ΔV is generated between the plasma processing chamber 10 and the cooling plate 131. Due to this potential difference, there is a possibility that abnormal discharge occurs in the through-hole 400h.

To address this, the flow path forming member 400 includes an upper porous plug 410 and a lower porous plug 420 disposed in the through-hole 400h, and a plurality of fluid particles 430 that fill the space between the upper porous plug 410 and the lower porous plug 420 in the through-hole 400h. At least one of the upper porous plug 410 or the lower porous plug 420 is detachably provided in the flow path forming member 400. With such a configuration, abnormal discharge can be suppressed.

The upper porous plug 410, the lower porous plug 420, and the fluid particles 430 are similar to the upper porous plug 210, the lower porous plug 220, and the fluid particles 230 (230A, 230B, 240), and thus the redundant description will be omitted.

The embodiments disclosed above include, for example, the following aspects.

### (Clause 1)

A substrate support comprising:
a main body portion having a substrate supporting surface and a back surface opposite to the substrate supporting surface, the main body portion having a through-hole extending from the back surface to the substrate supporting surface;
an upper porous plug and a lower porous plug disposed in the through-hole, at least one of the upper porous plug or the lower porous plug being detachable from the main body; and
a plurality of fluid particles filling a space between the upper porous plug and the lower porous plug in the through-hole, wherein
each of the plurality of fluid particles is formed of an Si-containing material or a resinous material and an Si-containing coating on the resinous material.

### (Clause 2)

The substrate support according to Clause 1, wherein
the main body is formed of a ceramic material.

### (Clause 3)

The substrate support according to Clause 1, wherein
the main body includes a conductive base and a ceramic member disposed on the conductive base,
the through-hole includes an upper through-hole formed in the ceramic member and a lower through-hole formed in the conductive base,
the upper porous plug is disposed in the upper through-hole, and
the lower porous plug is disposed in the lower through-hole.

### (Clause 4)

The substrate support according to any one of Clauses 1 to 3, wherein
the Si-containing material includes silicon or SiO₂.

### (Clause 5)

The substrate support according to any one of Clauses 1 to 3, wherein
the Si-containing coating includes SiC.

### (Clause 6)

The substrate support according to Clause 5, wherein
the resinous material contains polytetrafluoroethylene.

### (Clause 7)

The substrate support according to any one of Clauses 1 to 6, wherein
the upper porous plug has a first maximum pore size,
the lower porous plug has a second maximum pore size, and
each of the plurality of fluid particles has a particle size greater than the first maximum pore size and the second maximum pore size.

### (Clause 8)

The substrate support according to Clause 7, wherein
the plurality of fluid particles includes
   a plurality of first fluid particles each having a first particle size, and
   a plurality of second fluid particles each having a second particle size smaller than the first particle size.

### (Clause 9)

The substrate support according to Clause 8, wherein
the first particle size is in a range of 100 μm to 200 μm, and
the second particle size is less than 30 μm.

### (Clause 10)

The substrate support according to Clause 8 or 9, wherein
the first fluid particles and the second fluid particles are formed of a same material.

### (Clause 11)

The substrate support according to Clause 8 or 9, wherein
the first fluid particles and the second fluid particles are formed of different materials.

### (Clause 12)

A substrate support comprising:
a main body portion having a substrate supporting surface and a back surface opposite to the substrate supporting surface, the main body portion having a through-hole extending from the back surface to the substrate supporting surface;
an upper porous plug and a lower porous plug disposed in the through-hole, at least one of the upper porous plug or the lower porous plug being detachable from the main body, the upper porous plug having a first maximum pore size, the lower porous plug having a second maximum pore size; and
a plurality of fluid particles filling a space between the upper porous plug and the lower porous plug in the through-hole, wherein
the plurality of fluid particles includes
   a plurality of first fluid particles having a first particle size greater than the first maximum pore size and the second maximum pore size, and
   a plurality of second fluid particles having a second particle size greater than the first maximum pore size and the second maximum pore size and smaller than the first particle size.

### (Clause 13)

The substrate support according to Clause 12, wherein
the main body is formed of a ceramic material.

### (Clause 14)

The substrate support according to Clause 12, wherein
the main body includes a conductive base and a ceramic member disposed on the conductive base,
the through-hole includes an upper through-hole formed in the ceramic member and a lower through-hole formed in the conductive base,
the upper porous plug is disposed in the upper through-hole, and
the lower porous plug is disposed in the lower through-hole

### (Clause 15)

The substrate support according to any one of Clauses 12 to 14, wherein
the first particle size is in a range of 100 μm to 200 μm, and
the second particle size is less than 30 μm.

### (Clause 16)

The substrate support according to any one of Clauses 12 to 15, wherein
the first fluid particles and the second fluid particles are formed of a same material.

### (Clause 17)

The substrate support according to any one of Clauses 12 to 15, wherein
the first fluid particles and the second fluid particles are formed of different materials.

### (Clause 18)

A method of regenerating a substrate support, the substrate support including
a main body portion having a substrate supporting surface and a back surface opposite to the substrate supporting surface, the main body portion having a through-hole extending from the back surface to the substrate supporting surface,
an upper porous plug and a lower porous plug disposed in the through-hole, at least one of the upper porous plug or the lower porous plug being detachable from the main body, and
a plurality of fluid particles filling a space between the upper porous plug and the lower porous plug in the through-hole,
the method of regenerating comprising:
a step of removing at least one of the upper porous plug or the lower porous plug from the main body, at least one of the upper porous plug or the lower porous plug being detachable;
a step of removing a plurality of used fluid particles from the through-hole;
a step of filling the through-hole with a plurality of unused fluid particles; and
a step of attaching at least one of the upper porous plug or the lower porous plug to the main body, the at least one of the upper porous plug or the lower porous plug having been removed.

### (Clause 19)

The method of regenerating a substrate support of Clause 18, wherein
at least one of the step of removing the plurality of used fluid particles from the through-hole or the step of filling the through-hole with the plurality of unused fluid particles into the through-hole is performed while ultrasonic vibration is being applied to the main body.

The present invention is not limited to the configurations described in the above embodiments, and may be combined with other elements. These points can be changed without departing from the spirit of the present invention, and can be appropriately determined according to the application form.

What is claimed is:

1. A substrate support comprising:
a main body portion having a substrate supporting surface and a back surface opposite to the substrate supporting surface, the main body portion having a through-hole extending from the back surface to the substrate supporting surface;
an upper porous plug and a lower porous plug disposed in the through-hole, at least one of the upper porous plug or the lower porous plug being detachable from the main body; and
a plurality of fluid particles filling a space between the upper porous plug and the lower porous plug in the through-hole, wherein
each of the plurality of fluid particles is formed of an Si-containing material or a resinous material and an Si-containing coating on the resinous material.

2. The substrate support of claim 1, wherein
the main body is formed of a ceramic material.

3. The substrate support of claim 1, wherein
the main body includes a conductive base and a ceramic member disposed on the conductive base,
the through-hole includes an upper through-hole formed in the ceramic member and a lower through-hole formed in the conductive base,
the upper porous plug is disposed in the upper through-hole, and
the lower porous plug is disposed in the lower through-hole.

4. The substrate support according to claim 1, wherein
the Si-containing material includes Si or SiO₂.

5. The substrate support according to claim 1, wherein
the Si-containing coating includes SiC.

6. The substrate support of claim 5, wherein
the resinous material contains polytetrafluoroethylene.

7. The substrate support according to claim 1, wherein
the upper porous plug has a first maximum pore size,
the lower porous plug has a second maximum pore size, and
each of the plurality of fluid particles has a particle size greater than the first maximum pore size and the second maximum pore size.

8. The substrate support of claim 7, wherein
the plurality of fluid particles includes
a plurality of first fluid particles each having a first particle size, and
a plurality of second fluid particles each having a second particle size smaller than the first particle size.

9. The substrate support of claim 8, wherein
the first particle size is in a range of 100 μm to 200 μm, and
the second particle size is less than 30 μm.

10. The substrate support of claim 8, wherein
the first fluid particles and the second fluid particles are formed of a same material.

11. The substrate support of claim 8, wherein
the first fluid particles and the second fluid particles are formed of different materials

12. A substrate support comprising:
a main body portion having a substrate supporting surface and a back surface opposite to the substrate supporting surface, the main body portion having a through-hole extending from the back surface to the substrate supporting surface;
an upper porous plug and a lower porous plug disposed in the through-hole, at least one of the upper porous plug or the lower porous plug being detachable from the main body, with the upper porous plug having a first maximum pore size and the lower porous plug having a second maximum pore size; and
a plurality of fluid particles filling a space between the upper porous plug and the lower porous plug in the through-hole, wherein
the plurality of fluid particles includes
a plurality of first fluid particles having a first particle size greater than the first maximum pore size and the second maximum pore size, and
a plurality of second fluid particles having a second particle size greater than the first maximum pore size and the second maximum pore size and smaller than the first particle size.

13. The substrate support of claim 12, wherein
the main body is formed of a ceramic material.

14. The substrate support of claim 12, wherein
the main body includes a conductive base and a ceramic member disposed on the conductive base,
the through-hole includes an upper through-hole formed in the ceramic member and a lower through-hole formed in the conductive base,
the upper porous plug is disposed in the upper through-hole, and
the lower porous plug is disposed in the lower through-hole.

15. The substrate support according to claim 12, wherein
the first particle size is in a range of 100 μm to 200 μm, and
the second particle size is less than 30 μm.

16. The substrate support of claim 15, wherein
the first fluid particles and the second fluid particles are formed of a same material.

17. The substrate support of claim 15, wherein
the first fluid particles and the second fluid particles are formed of different materials.

18. A method of regenerating a substrate support, the substrate support including
a main body portion having a substrate supporting surface and a back surface opposite to the substrate supporting surface, the main body portion having a through-hole extending from the back surface to the substrate supporting surface,
an upper porous plug and a lower porous plug disposed in the through-hole, at least one of the upper porous plug or the lower porous plug being detachable from the main body, and
a plurality of fluid particles filling a space between the upper porous plug and the lower porous plug in the through-hole,
the method of regenerating comprising:
removing at least one of the upper porous plug or the lower porous plug from the main body, at least one of the upper porous plug or the lower porous plug being detachable;
removing a plurality of used fluid particles from the through-hole;
filling the through-hole with a plurality of unused fluid particles; and
attaching at least one of the upper porous plug or the lower porous plug to the main body, the at least one of the upper porous plug or the lower porous plug having been removed.

19. The method of regenerating a substrate support of claim 18, wherein
at least one of the removing the plurality of used fluid particles from the through-hole or the filling the through-hole with the plurality of unused fluid particles is performed while ultrasonic vibration is being applied to the main body.
